(19) United States
(12) Patent Application Publication
(10) Pub. No.: US 2025/0279766 A1
(43) Pub. Date: Sep. 4, 2025

(54) CURRENT-REUSE CURRENT-MODE NOTCH FILTER

(71) Applicant: Sequans Communications SA, Colombes (FR)

(72) Inventor: Arash Abbasi, Reading (GB)

(21) Appl. No.: 18/591,521

(22) Filed: Feb. 29, 2024

(51) Int. Cl. H03H 11/04; H03F 3/45

(52) U.S. Cl. CPC H03H 11/0422; H03F 3/45475; H03F 2200/294; H03H 2011/0488

(57) ABSTRACT

Disclosed are example embodiments describing receiver circuits and methods for mitigating out-of-band blockers. The receiver circuits include a low noise transconductance amplifier (LNTA) stage, a down-conversion mixer stage, a post-mixer filter, and a gain stage. A feature is the reuse of supply currents from the post-mixer filter and the gain stage to supply the LNTA stage. The method involves down-converting an input signal, filtering the down converted signal through a current-mode notch filter, amplifying the filtered signal, and reusing a combined supply current for the LNTA stage.

### TECHNICAL FIELD

The disclosure relates generally to the field of wireless communication receivers, and specifically and not by way of limitation, some embodiments are related to current reuse circuitry.

### BACKGROUND

The proliferation of wireless devices, such as smartphones and Internet of Things (IoT) devices, and the increased likelihood of strong interference are raising concerns about the interference resilience of radio receivers. Additionally, the push for greater bandwidth driven by communication standards continues, while the frequency offsets of potential blockers remain constant. The advent of carrier aggregation further complicates this issue by expanding the overall bandwidth. These trends collectively pose greater challenges in effectively managing and mitigating interference from blockers.

FIG. 1 is a diagram illustrating a scenario within Long-Term Evolution (LTE) frequency division duplex (FDD) systems that occurs at the cell's outermost boundary, where handset 100 is located. Here, handset 100 receives an extremely weak signal, e.g., at an antenna 102, through a duplexer 104, and ultimately at a receiver 106, while a transmitter 108 operates at maximum power 120. Efficient suppression of nearby blockers may be used in such scenarios. Specifically, the problem of Tx leakage 110 (transmitter leakage), poses a significant concern, as Tx leakage 110 may degrade the ability of the receiver 106 to distinguish between the desired signal and interference.

FIG. 2 is a block diagram of a traditional receiver front-end 200. The illustrated traditional receiver front-end 200 includes an antenna 202, an LNA 204, a mixer 206, and a low pass filter 208. a traditional receiver front-end 200. The traditional receiver front-end 200 typically requires high-order filters to eliminate undesired noise and out-of-band blockers. However, this approach leads to increased power consumption and a larger area. Moreover, the filter must be highly linear to cope with strong blockers at the input. A more effective strategy involves eliminating out-of-band blockers just before the filter by employing a notch filter.

Extensive research efforts have been focused on improving the rejection of blockers in receiver front ends to suppress unwanted signals with very low frequencies that closely overlap with the desired frequency passband, op-amp-based notch filters in combination with resistor-capacitor (RC) networks were employed. In U.S. Pat. No. 3,375,451, an adaptive tracking notch filter system was presented for low-frequency operation, typically in the range of a few kilohertz. This system comprises multiple sub-circuits, which not only consume power but also contribute to increased system complexity. A 60 Hz notch filter designed to eliminate unwanted interference from power lines was introduced in U.S. Pat. No. 8,436,679. This filter utilized the Tow-Thomas topology and employed three op-amps, which are known to have high power consumption, especially at higher frequencies. In U.S. Pat. No. 9,344,124 and U.S. Pat. No. 9,209,910, an additional down-conversion route is employed to achieve both noise-cancellation and out-of-band interferer rejection. This technique consumes additional dynamic power and increases local-oscillator (LO) to radio frequency (RF) leakage. In Safarian, A., Shameli, A., Rofougaran, A., Rofougaran, M., & De Flaviis, F. (2007 June). Integrated blocker filtering RF front ends. In 2007 IEEE Radio Frequency Integrated Circuits (RFIC) Symposium (pp. 13-16). IEEE., RF blocker rejection before down-conversion is achieved using a cancellation module by generating an injection signal representative of the blocking signal, combining the blocking signal with the injection signal to produce an error signal, updating the injection signal based on the error signal, and using the injection signal to cancel the blocking signal from the amplified inbound RF signal. This approach increases the complexity of the design and power. Similarly, in U.S. Pat. No. 10,547,289, the out-of-band attenuation is achieved using an RF mode N-path filter that requires additional LNA and local oscillator (LO) routing, which consumes more power. Another N-path receiver approach is introduced in U.S. Pat. No. 9,413,400 to reject transmitter leakage that requires more power, area, and LO routing that consumes more dynamic power. A pilot-based analog active interference canceller is utilized in U.S. Pat. No. 9,800,287, which requires complex both baseband and analog circuitry that increases power consumption. To address the issue mentioned earlier, in Jiang, J., Kim, J., Karsilayan, A. I., & Silva-Martinez, J. (2019). A 3-6-GHz highly linear I-channel receiver with over+3.0-dBm in-band PldB and 200-MHz baseband bandwidth suitable for 5G wireless and cognitive radio applications. IEEE Transactions on Circuits and Systems I: Regular Papers, 66(8), 3134-3147; Abdulaziz, M., Klumperink, E. A., Nauta, B., & Sjöland, H. (2018). Improving Receiver Close-In Blocker Tolerance by Baseband Gₘ-C Notch Filtering. IEEE Transactions on Circuits and Systems I: Regular Papers, 66(3), 885-896; and Silva-Pereira, M., de Sousa, J. T., Freire, J. C., & Vaz, J. C. (2018). A 1.7-mW-92-dBm Sensitivity Low-IF Receiver in 0.13-μm CMOS for Bluetooth LE Applications. IEEE Transactions on Microwave Theory and Techniques, 67(1), 332-346., a current-mode notch filter is employed after the mixer right before the transimpedance amplifier (TIA). This notch filter uses a single operational transconductance amplifier (OTA) in conjunction with an RC network placed just before the TIA to eliminate out-of-band blockers, as depicted in FIG. 3. Thanks to the OTA's high-frequency operation, the notch filter is capable of effectively filtering out high-frequency blockers. Nevertheless, the combination of the notch filter with the conventional receiver architecture results in high current consumption, specifically:

I₁+I₂+I₃.

FIG. 3 is a block diagram of a receiver 300 with a current-mode notch filter 302 (see, e.g., U.S. Pat. No. 9,344,124). Recently, a current-reuse receiver architecture has emerged, which involves stacking multiple current-consuming components like low noise transconductance amplifier (LNTA) 304, mixer 306, and baseband circuitry 308 to mitigate current consumption. In reference U.S. Pat. No. 9,356,636, an RF-to-BB-current-reuse wideband receiver was introduced, featuring parallel N-Path active/passive mixers and a single-MOS pole-zero LPF, operating at sub-GHz frequencies. The included notch filter offers excellent rejection of out-of-band blockers.

FIG. 4 is a current reuse receiver 400 using an N-path active/passive mixer, including baseband circuitry 402, a notch filter 404, a mixer 406, and an LNTA 408, wherein the voltage supply is used linearly through the components one after the other. However, the choice of an active mixer necessitates the use of a high voltage power supply, set at 2.5V as illustrated in FIG. 4. Additionally, the voltage-mode notch filter also consumes a portion of the available voltage headroom. In small technology nodes such as 22FDX global foundries, the lack of 2.5V device makes this architecture undesirable.

To address the aforementioned challenge, a current-reuse receiver was introduced, featuring a passive mixer, where the LNTA, active inductor, and transimpedance amplifier (TIA) are stacked has been proposed in Abbasi, A., Moshrefi, A. H., & Nabki, F. (2022). A wideband low-power RF-to-BB current-reuse receiver using an active inductor and 1/f noise-cancellation for L-band applications. IEEE Access, 10, 95839-95848. This design allows for a reduced supply voltage of 1.2V. However, it encounters an issue due to the absence of a notch filter to eliminate out-of-band blockers, resulting in a poor out-of-band third-order intercept point (IIP3) performance.

To overcome issues mentioned in the state-of-the-art, the instant application proposes a current-reuse receiver topology along with the current-reuse current-mode notch filter that may utilize a lower voltage supply when compared to other topologies.

### SUMMARY

Example implementations include embodiments describing receiver circuits and methods for mitigating out-of-band blockers. The receiver circuits include a low noise transconductance amplifier (LNTA) stage, a down-conversion mixer stage, a post-mixer filter, and a gain stage. A feature is the reuse of supply currents from the post-mixer filter and the gain stage to supply the LNTA stage. The method involves down-converting an input signal, filtering the down converted signal through a current-mode notch filter, amplifying the filtered signal, and reusing a combined supply current for the LNTA stage.

Disclosed are example embodiments of a receiver circuit including a low noise transconductance amplifier (LNTA) stage, a down-conversion mixer stage, a post-mixer filter; and a gain stage. In the receiver circuit a supply currents of the post-mixer filter and the gain stage are combined and re-used to supply the LNTA stage.

Disclosed are example embodiments of a method for mitigating out-of-band blockers in a receiver circuit. The method includes providing a low noise transconductance amplifier (LNTA) stage, down-converting an input signal in a passive mixer stage, filtering the down-converted signal in a current-mode notch filter post-mixer, amplifying the filtered signal in a gain stage, and re-using a combined supply current of the current-mode notch filter and the gain stage to supply the LNTA stage.

Disclosed are example embodiments of a receiver circuit for mitigating out-of-band blockers. The receiver circuit includes means for low noise amplification, means for down-converting an input signal, means for filtering the down-converted signal using a current-mode notch filter, means for amplifying the filtered signal, and means for re-using a combined supply current of the means for filtering and the means for amplifying to supply the low noise amplification means.

The features and advantages described in the specification are not all-inclusive. In particular, many additional features and advantages will be apparent to one of ordinary skill in the art in view of the drawings, specification, and claims. Moreover, it should be noted that the language used in the specification has been principally selected for readability and instructional purposes and may not have been selected to delineate or circumscribe the disclosed subject matter.

### BRIEF DESCRIPTION OF THE DRAWINGS

The foregoing summary, as well as the following detailed description, is better understood when read in conjunction with the accompanying drawings. The accompanying drawings, which are incorporated herein and form part of the specification, illustrate a plurality of embodiments and, together with the description, further serve to explain the principles involved and to enable a person skilled in the relevant art(s) to make and use the disclosed technologies.

FIG. 1 is a diagram illustrating a scenario within LTE frequency division duplex systems that occurs at the cell's outermost boundary, where the handset is located.

FIG. 2 is a block diagram of a traditional receiver front-end, which typically requires high-order filters to eliminate undesired noise and out-of-band blockers.

FIG. 3 is a block diagram of a receiver with current mode notch filter.

FIG. 4 is a current reuse receiver using an N-path active/passive mixer.

FIG. 5 is a diagram illustrating a first proposed circuit using an operational transconductance amplifier (OTA) to form the notch filter at the output of the passive mixer.

FIG. 6 is a diagram illustrating a second proposed circuit using a current-reuse current-mode notch filter, which may result in a substantial reduction in power consumption.

FIG. 7 is a block diagram illustrating that the direct current (DC) current of the notch filter may be shared with one or more circuits before being used by another block such as LNTA.

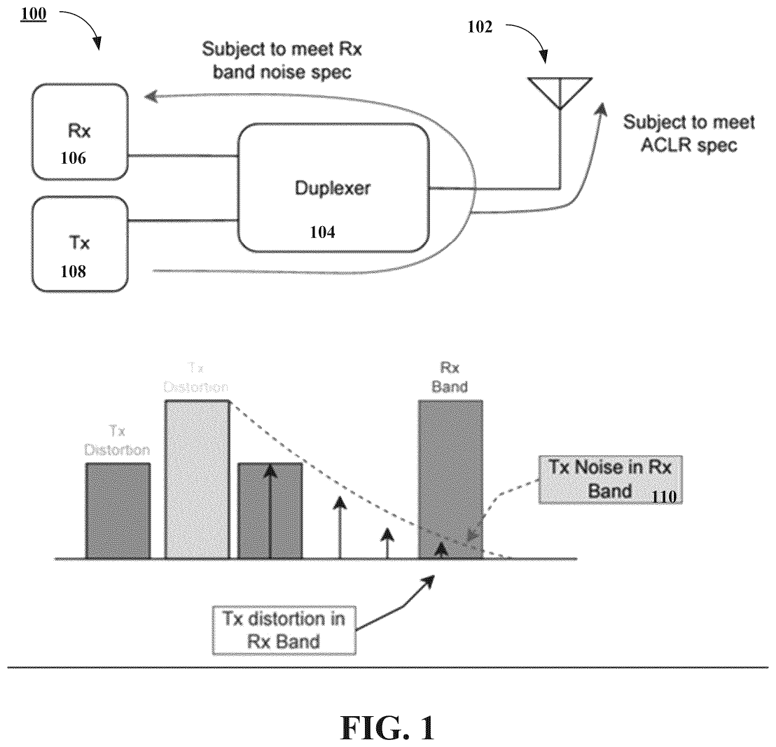

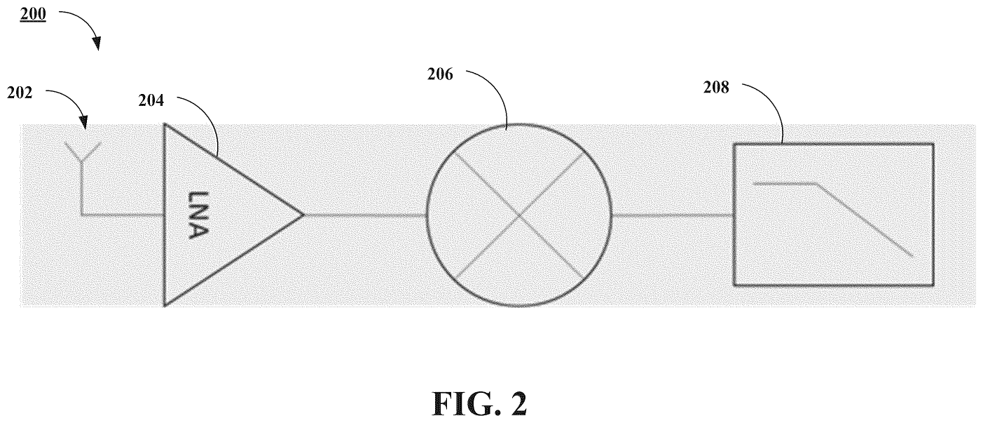

The figures and the following description describe certain embodiments by way of illustration only. One skilled in the art will readily recognize from the following description that alternative embodiments of the structures and methods illustrated herein may be employed without departing from the principles described herein. Reference will now be made in detail to several embodiments, examples of which are illustrated in the accompanying figures. It is noted that wherever practicable similar or like reference numbers may be used in the figures to indicate similar or like functionality.

### DETAILED DESCRIPTION

In wireless communication receivers, current-reuse circuitry is a technique employed to enhance power efficiency by reusing the same current through multiple stages of the receiver. While existing solutions may be capable of suppressing out-of-band blockers in wireless communication receivers, they often do so at the expense of increased power consumption. Some embodiments of the instant application addresses this issue by employing a current-reuse architecture that stacks multiple circuit components, such as the low noise transconductance amplifier (LNTA), mixer, and filter stages, to achieve efficient blocker suppression while significantly reducing power consumption. Some embodiments may have applications in a variety of wireless communication systems, including but not limited to, Internet of Things (IoT) devices, 5G wireless networks, and other radio systems or circuits. Various embodiments power-efficient design may make it particularly suitable for battery-operated devices where energy conservation may be more advantageous. Current-reuse may be applied to one or more of the circuits described below.

The present disclosure relates to a receiver circuit that may be designed to mitigate out-of-band blockers in wireless communication systems. The receiver circuit may include several stages that may work together to potentially improve signal quality and reduce interference. The receiver circuit may be configured to take advantage of current reuse.

In an example embodiment, a Low Noise Transconductance Amplifier (LNTA) stage may be used for amplifying weak signals with minimal added noise. The LNTA Stage may provide initial signal amplification. Various LNTA topologies may be employed, including a capacitive cross-coupled common-gate (CCC-CG) topology, which may be known for its wideband radio frequency (RF) input matching capabilities. The LNTA may be configured to take advantage of current reuse, e.g., in conjunction with one or more other circuits described herein.

In an example embodiment, a down-conversion mixer stage may convert the high-frequency RF signal to a lower frequency, making it easier to process in subsequent stages. A passive mixer may be used for this purpose due to its simplicity and low power consumption. These circuits may also be configured to take advantage of current reuse, e.g., in conjunction with one or more other circuits described herein, and/or with each other.

In an example embodiment, a post-mixer filter may be used, e.g., after down-conversion. For example, the signal may be passed through a post-mixer filter to remove unwanted signals and noise. This filter may be implemented as a current-mode notch filter, which can be realized using either an operational transconductance amplifier (OTA) combined with an RC circuit or a current-reuse current-mode notch filter topology. The latter approach may be advantageous for reducing power consumption, as it allows for the reuse of half of the current consumed by the gain stage. The post-mixer filter may be configured to take advantage of current reuse, e.g., in conjunction with one or more other circuits described herein.

In an example embodiment, a gain stage, typically implemented using a transimpedance amplifier (TIA), may amplify the filtered signal to a level suitable for further processing or output. The design of the TIA may be optimized to work efficiently with the reduced current supplied by the current-reuse mechanism. The gain stage may be configured to take advantage of current reuse, e.g., in conjunction with one or more other circuits described herein.

As discussed above, in an example embodiment, a feature of the receiver circuit may be the reuse of supply currents from the post-mixer filter and the gain stage to supply the LNTA stage. This current reuse mechanism may enhance the overall power efficiency of the receiver circuit, making it suitable for low-power applications such as short-range IoT devices.

The method for mitigating out-of-band blockers in the receiver circuit may involve providing the LNTA stage, down-converting the input signal in the passive mixer stage, filtering the down-converted signal in the current-mode notch filter post-mixer, amplifying the filtered signal in the gain stage, and re-using the combined supply currents of the current-mode notch filter and the gain stage to supply the LNTA stage.

By employing these stages and mechanisms, the receiver circuit may effectively mitigate out-of-band blockers while optimizing power consumption, thereby potentially improving the performance and efficiency of wireless communication systems.

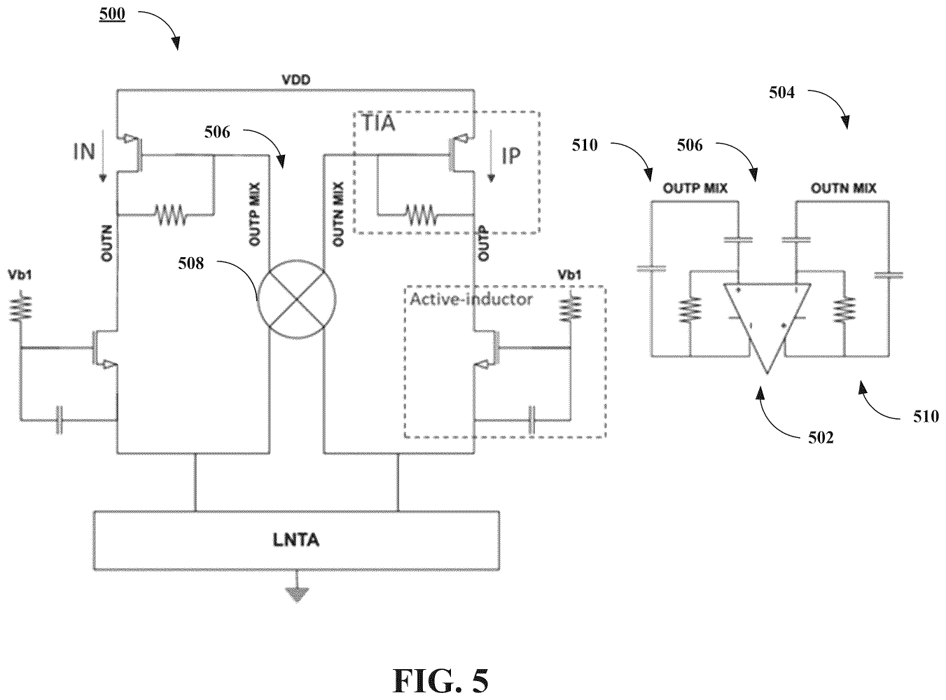

FIG. 5 is a diagram illustrating a first proposed circuit 500 using an operational transconductance amplifier (OTA) 502 to form the notch filter 504 at the output 506 of the passive mixer 508. This circuit 500 may address the challenges of out-of-band blockers in a current-mode signal, which can significantly impact the performance of radio frequency (RF) receivers. By employing the OTA 502 in conjunction with an resistor-capacitor (RC) network 510, the circuit 500 effectively creates a low-impedance node at the mixer's output. This configuration allows for the attenuation of blocker signals that fall outside the desired frequency band, ensuring that the receiver can focus on the intended signal without interference. The use of the OTA 502 in this circuit 500 may be used, as the OTA 502 may provide the necessary transconductance to implement the notch filter while also managing to conserve headroom, which is a significant advantage over traditional approaches.

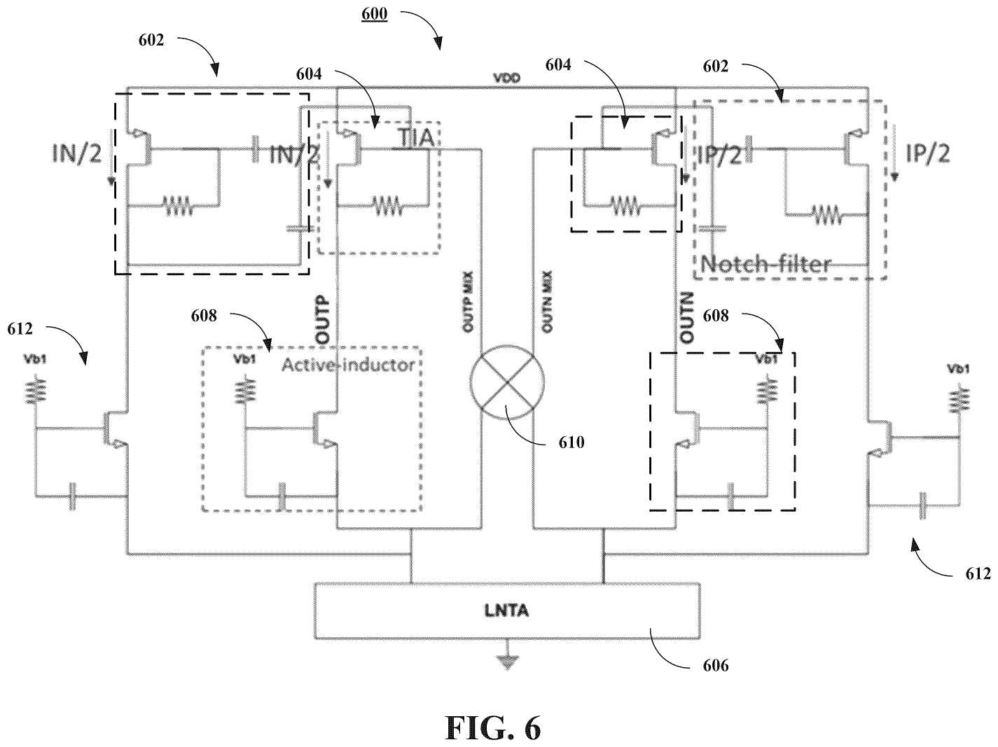

FIG. 6 is a diagram illustrating a second proposed circuit 600 using a current-reuse current-mode notch filter 602, which may result in a substantial reduction in power consumption. This circuit design leverages the concept of current reuse to enhance efficiency. By redirecting half of the current consumed by the transimpedance amplifier (TIA) 604 to power the current-reuse current-mode notch filter 602, the second proposed circuit 600 minimizes overall power usage without compromising performance. This approach may be beneficial in low-power applications where energy efficiency is paramount. Additionally, the integration of the current-reuse current-mode notch filter 602 in this configuration ensures effective blocker attenuation while maintaining a minimal impact on the noise figure (NF) of the receiver, thanks to the primary influence of the low noise transconductance amplifier (LNTA) 606 on NF performance. The second proposed circuit 600 may also include mixer 610, an active inductor 608, and additional circuitry 612.

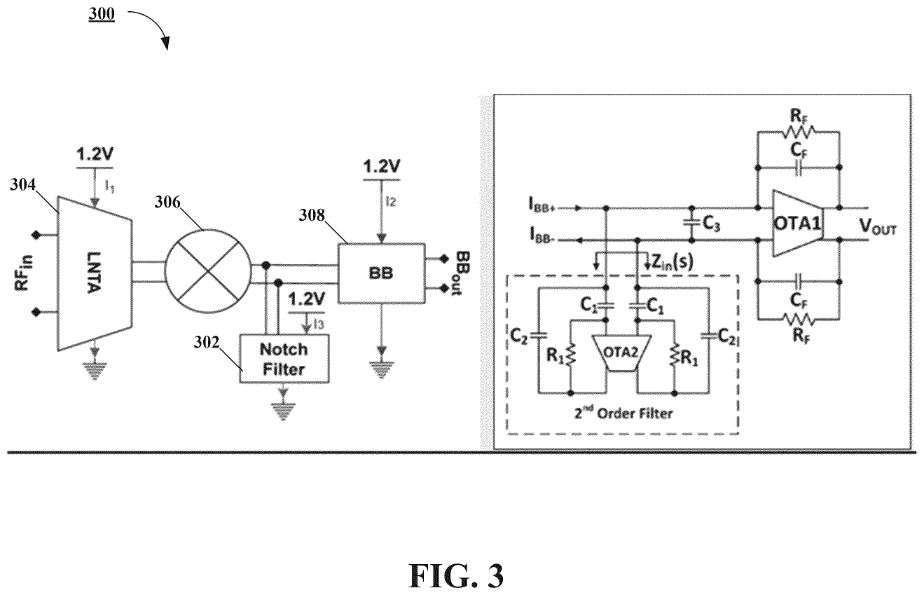

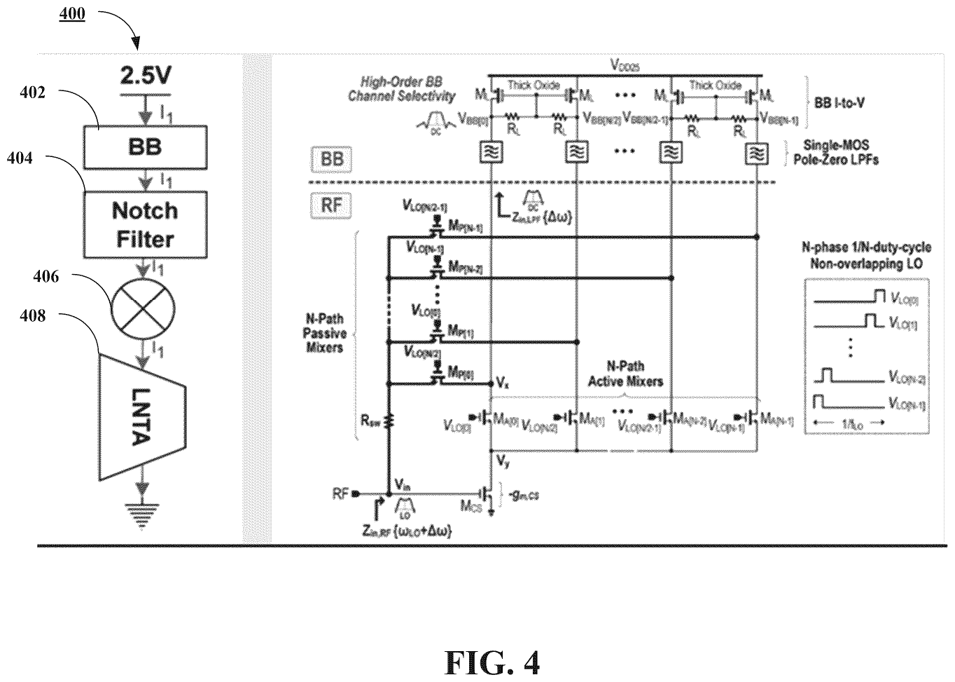

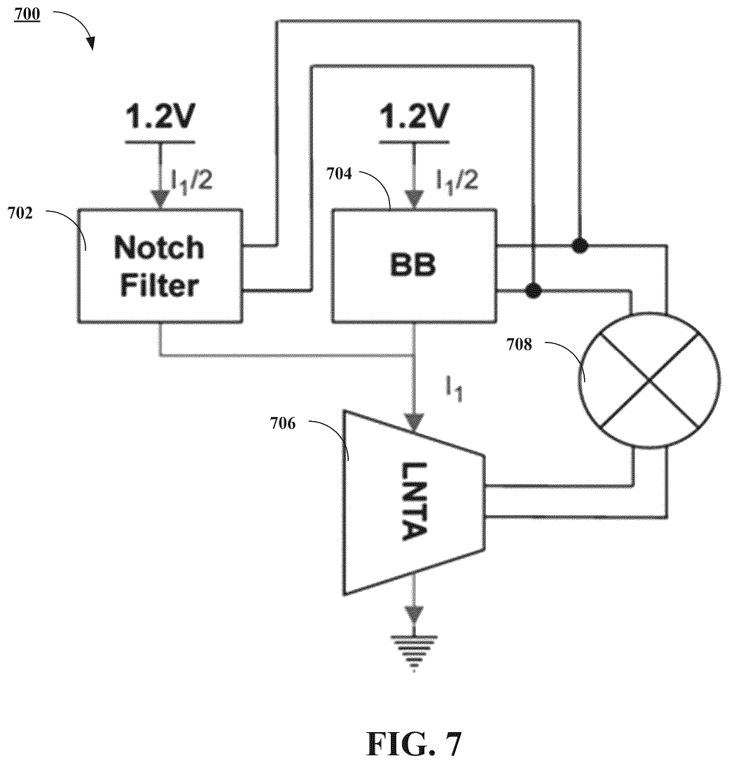

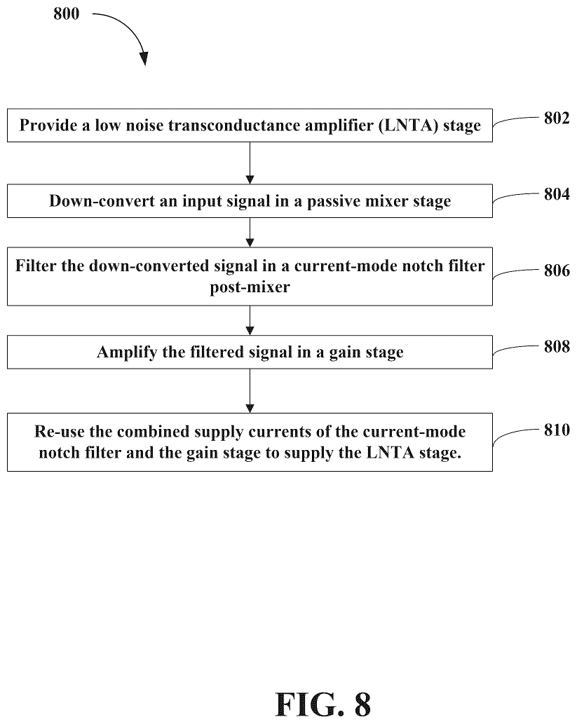

FIG. 7 is a block diagram 700 illustrating that the DC current (I₁) of the notch filter 702 (I₁/2) may be shared with one or more circuits, e.g., based band circuitry 704 (I₁/2) before being used by another block such as LNTA 706 (I₁). This sharing of DC current (I₁) is an aspect of the current-reuse strategy, which may optimize power distribution within the receiver circuit. By allowing the DC current (I₁) to be utilized by multiple components, e.g., notch filter 702, based band circuitry 704, and LNTA 706, the design enhances the overall efficiency of the system. The flexibility of this approach is further highlighted by the fact that the supply voltage can be set to any value, with 1.2V being provided as an example. This adaptability ensures that the current-reuse receiver front-end can be tailored to meet the specific requirements of various applications. As illustrated in FIG. 3, the signal flow for FIG. 7 may include the LNTA 706 coupled to an input of the mixer 708, and the output of the mixer 708 coupled to the notch filter 702 and the base band circuitry 704. As discussed above, however, the power provided may use a different topology.

The current-reuse topology in the proposed receiver circuit may not only optimize power distribution but may also contribute to minimizing power consumption, which may be important for battery-powered devices. By sharing the DC current among various components, the circuit may reduce the total amount of current drawn from the power supply, which may lead to prolonged battery life and enhanced energy efficiency. One or more of the approaches described herein may be particularly advantageous in the design of portable wireless devices, where power conservation may be paramount. Furthermore, the ability to set the supply voltage to any value may add a layer of versatility to the circuit design, allowing a circuit design to be adapted to different technological requirements and standards. The current-reuse strategy may balance performance with power efficiency, making the current-reuse strategy a suitable solution for various electronic circuits, including modern wireless communication systems.

The concepts illustrated in FIGS. 5, 6, and 7 may be applied to other circuits. For example, OTA-based notch filters that include the approach of using an operational transconductance amplifier (OTA) combined with an RC network to create a notch filter (as illustrated in FIG. 5) may be employed in various RF circuits to attenuate specific frequency bands, thereby improving signal integrity.

The current-reuse topology discussed herein, where a portion of the current consumed by one component is redirected to power another component, may be applied to various low-power electronic designs to enhance energy efficiency. For example, this approach involves redirecting a portion of the current consumed by one component, such as the transimpedance amplifier (TIA), to power another component, like the current-reuse current-mode notch filter. By minimizing overall power usage without compromising performance, this topology may be particularly beneficial for low-power applications where energy efficiency may be paramount. The concept may be adapted and integrated into various electronic designs to reduce power consumption and extend battery life in portable devices.

For example, the current-reuse topology may be used in applications in different types of circuits beyond just RF receivers. For example, the systems and methods described herein may be applied in analog-to-digital converters, power management circuits, or sensor interfaces, to name a few example circuits. The systems and methods described herein may be used to improve energy efficiency. Additionally, the concept may be extended to incorporate dynamic current allocation based on the circuit's operational state, further optimizing power usage. This approach may be particularly useful in systems with varying power requirements, such as wireless communication devices that switch between active and standby modes.

Additionally, the shared DC current strategy among multiple circuit components (as depicted in FIG. 7) can be utilized in integrated circuits to optimize power distribution and reduce overall power consumption. These approaches can be tailored and integrated into different circuit designs depending on the specific requirements and constraints of the application.

In some example embodiments, the current-reuse topology and shared DC current strategy may work effectively with RF signals. The RF signals are alternating in nature, and the circuits are designed to process these signals while managing DC power efficiently. For example, some embodiments may use capacitive coupling to separate the RF signal components from the DC supply voltages, allowing the circuit to process the RF signals without interference from the DC supply.

Capacitive coupling is a technique used to transfer alternating electrical signals or energy from one part of a circuit to another using a capacitor. This method allows AC signals, e.g., RF signals, to pass while blocking DC energy, making it suitable for isolating different stages of a circuit, such as the input and output stages of an amplifier. In analog circuits, capacitive coupling is used to connect two circuits in such a way that only the AC component of the signal passes from one circuit to the other, while blocking and isolating the DC bias voltage. Accordingly, the supply voltage, which may be at different DC voltages across different components that may all be transforming the RF signal(s) does not directly affect the signal processing part of the circuit, enabling efficient use of power.

FIG. 8 is a flow diagram illustrating an example method 800 for mitigating out-of-band blockers in a receiver circuit in accordance with the systems and methods described herein. Method 800 for mitigating out-of-band blockers in a receiver circuit includes providing a low noise transconductance amplifier (LNTA) stage (802). The method 800 also includes down converting an input signal in a passive mixer stage (804). Additionally, the method 800 includes filtering the down-converted signal in a current-mode notch filter post-mixer (806). The method 800 also includes amplifying the filtered signal in a gain stage (808). Additionally, method 800 includes re-using a combined supply current of the current-mode notch filter and the gain stage to supply the LNTA stage (810).

Method 800 for mitigating out-of-band blockers in a receiver circuit includes providing a low noise transconductance amplifier (LNTA) stage (802). In this step, the method involves setting up a low noise amplification stage using an LNTA. The LNTA may be used for amplifying weak signals with minimal added noise, which is essential for maintaining the integrity of the received signal. The implementation of the LNTA can be further optimized using a capacitive cross-coupled common-gate (CCC-CG) topology. This topology is known for providing wideband RF input matching, which is beneficial for accommodating a range of frequencies without compromising noise performance.

The method 800 also includes down converting an input signal in a passive mixer stage (804). The method proceeds with down converting the input signal in a passive mixer stage. The passive mixer is chosen for its simplicity and low power consumption, making the passive mixer suitable for applications where energy efficiency is a priority. The down-conversion process is critical for converting the high-frequency RF signal to a lower frequency, which is easier to process and filter in subsequent stages.

Additionally, method 800 includes filtering the down-converted signal in a current-mode notch filter post-mixer (806). In this step, the down-converted signal is filtered using a current-mode notch filter. The implementation of this filter may vary. One approach is to use an operational transconductance amplifier (OTA) combined with an RC circuit, which creates a low-impedance node at the output of the mixer for effective blocker attenuation. Alternatively, a current-reuse current-mode notch filter topology can be employed, which enhances power efficiency by reusing part of the current consumed by the gain stage.

The method 800 also includes amplifying the filtered signal in a gain stage (808). The method includes amplifying the filtered signal in a gain stage, typically using a transimpedance amplifier (TIA). The TIA converts the current signal into a voltage signal, preparing the signal for further processing or output. In the context of a current-reuse strategy, the design of the TIA is optimized to work efficiently with the reduced current supplied by the current-reuse mechanism, ensuring that the amplification process does not compromise the overall power efficiency of the receiver circuit.

Additionally, method 800 includes re-using the combined supply currents of the current-mode notch filter and the gain stage to supply the LNTA stage (810). For example, the method involves reusing the combined supply currents of the current-mode notch filter and the gain stage to supply the LNTA stage. This step may be used in the current-reuse strategy, as the step may enhance the overall power efficiency of the receiver circuit. By sharing and redirecting the DC currents among different components, the receiver circuit may achieve effective mitigation of out-of-band blockers while optimizing power consumption, which may make the receiver circuit suitable for low-power applications such as short-range IoT devices.

In some examples, a means for low noise amplification may include, a Low Noise Transconductance Amplifier (LNTA), which may be a component in the receiver circuit in some embodiments. The LNTA may be used for amplifying weak signals with minimal added noise. The LNTA may be designed with various topologies, such as the capacitive cross-coupled common-gate (CCC-CG) topology described herein. The CCC-CG topology is generally known for its wideband RF input matching capabilities. This topology may help in achieving low noise amplification across a broad range of frequencies.

In some examples, a means for down-converting an input signal may include, but is not limited to, a passive mixer. The passive mixer may be used for the down-conversion process for converting the high-frequency RF signal to a lower frequency for easier processing. Passive mixers may be favored for their simplicity and low power consumption, making them suitable for low-power applications.

In some examples, a means for filtering the down-converted signal may include but is not limited to a current-mode notch filter that may be employed for filtering the down-converted signal, with a specific embodiment being a current-reuse current-mode notch filter. This type of filter may be advantageous because the filter may not only attenuate out-of-band blockers but may also contribute to power savings by reusing current within the circuit.

In some examples, a means for amplifying the filtered signal may be a filter to amplify to a level suitable for further processing or output. This amplification may typically done using a Transimpedance Amplifier (TIA), but is not limited to such an amplifier. The TIA may convert the current signal into a voltage signal. In the context of the current-reuse strategy, the TIA's design may be optimized to work efficiently with the reduced current provided by the current-reuse mechanism.

In some examples, a means for re-using the combined supply currents may include, but is not limited to, the proposed receiver circuit that may include the re-use of supply currents from the post-mixer filter and the gain stage (TIA) to supply the LNTA. This is achieved through a carefully designed circuit layout that allows the DC current of the notch filter and the TIA to be shared and redirected to power the LNTA. This approach may enhance the overall power efficiency of the receiver circuit, which may make the approach suitable for low-power applications such as short-range IoT devices.

These figures are provided to illustrate and explain the concepts of the invention. It should be noted that they are not exhaustive and other configurations and embodiments are possible within the scope of the invention.

One or more of the components, steps, features, and/or functions illustrated in the figures may be rearranged and/or combined into a single component, block, feature or function or embodied in several components, steps, or functions. Additional elements, components, steps, and/or functions may also be added without departing from the disclosure. The apparatus, devices, and/or components illustrated in the Figures may be configured to perform one or more of the methods, features, or steps described in the Figures. The algorithms described herein may also be efficiently implemented in software and/or embedded in hardware.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description are presented in terms of algorithms and symbolic representations of operations on data bits within a computer memory. These algorithmic descriptions and representations are the methods used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared or otherwise manipulated. It has proven convenient at times, principally for reasons of common usage, to refer to these signals as bits, values, elements, symbols, characters, terms, numbers or the like.

It should be borne in mind, however, that all of these and similar terms are to be associated with the appropriate physical quantities and are merely convenient labels applied to these quantities. Unless specifically stated otherwise as apparent from the following disclosure, it is appreciated that throughout the disclosure terms such as “processing,” “computing,” “calculating,” “determining,” “displaying” or the like, refer to the action and processes of a computer system, or similar electronic computing device, that manipulates and transforms data represented as physical (electronic) quantities within the computer system's registers and memories into other data similarly represented as physical quantities within the computer system's memories or registers or other such information storage, transmission or display.

Finally, the algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear from the description below. It will be appreciated that a variety of programming languages may be used to implement the teachings of the invention as described herein.

The foregoing description of the embodiments of the present invention has been presented for the purposes of illustration and description. It is not intended to be exhaustive or to limit the present invention to the precise form disclosed. Many modifications and variations are possible in light of the above teaching. It is intended that the scope of the present invention be limited not by this detailed description, but rather by the claims of this application. As will be understood by those familiar with the art, the present invention may be embodied in other specific forms without departing from the spirit or essential characteristics thereof. Likewise, the particular naming and division of the modules, routines, features, attributes, methodologies and other aspects are not mandatory or significant, and the mechanisms that implement the present invention or its features may have different names, divisions and/or formats.

Furthermore, as will be apparent to one of ordinary skill in the relevant art, the modules, routines, features, attributes, methodologies and other aspects of the present invention can be implemented as software, hardware, firmware or any combination of the three. Also, wherever a component, an example of which is a module, of the present invention is implemented as software, the component can be implemented as a standalone program, as part of a larger program, as a plurality of separate programs, as a statically or dynamically linked library, as a kernel loadable module, as a device driver, and/or in every and any other way known now or in the future to those of ordinary skill in the art of computer programming.

Additionally, the present invention is in no way limited to implementation in any specific programming language, or for any specific operating system or environment. Accordingly, the disclosure of the present invention is intended to be illustrative, but not limiting, of the scope of the present invention, which is set forth in the following claims.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A receiver circuit comprising:
a low noise transconductance amplifier (LNTA) stage;
a down-conversion mixer stage;
a post-mixer filter; and
a gain stage,
wherein supply currents of the post-mixer filter and the gain stage are combined and re-used to supply the LNTA stage.

2. The receiver circuit of claim 1, wherein the down-conversion mixer stage is a passive mixer.

3. The receiver circuit of claim 1, wherein the post-mixer filter is a current-mode notch filter.

4. The receiver circuit of claim 3, wherein the current-mode notch filter is implemented using an operational transconductance amplifier (OTA) combined with an RC circuit to create a low-impedance node at an output of the down-conversion mixer stage for frequencies outside a band of operation.

5. The receiver circuit of claim 3, wherein the current-mode notch filter is implemented using a current-reuse current-mode notch filter topology.

6. The receiver circuit of claim 5, wherein half of the current consumed by the gain stage is redirected to power the current-reuse current-mode notch filter.

7. The receiver circuit of claim 6, wherein a noise figure (NF) performance of the receiver circuit is primarily influenced by the LNTA, and various LNTA topologies can be employed.

8. The receiver circuit of claim 7, wherein a capacitive cross-coupled common-gate (CCC-CG) LNTA topology is utilized to provide wideband RF input matching.

9. The receiver circuit of claim 1, wherein a supply voltage of the receiver circuit can be any value.

10. The receiver circuit of claim 9, wherein the supply voltage is exemplarily 1.2V.

11. A method for mitigating out-of-band blockers in a receiver circuit, comprising:
providing a low noise transconductance amplifier (LNTA) stage;
down-converting an input signal in a passive mixer stage;
filtering the down-converted signal in a current-mode notch filter post-mixer;
amplifying the filtered signal in a gain stage; and
re-using a combined supply current of the current-mode notch filter and the gain stage to supply the LNTA stage.

12. The method of claim 11, wherein the current-mode notch filter is implemented using an operational transconductance amplifier (OTA) combined with an RC circuit.

13. The method of claim 11, wherein the current-mode notch filter is implemented using a current-reuse current-mode notch filter topology.

14. The method of claim 13, wherein half of the current consumed by the gain stage is redirected to power the current-reuse current-mode notch filter.

15. The method of claim 11, further comprising employing a capacitive cross-coupled common-gate (CCC-CG) LNTA topology for the LNTA stage to provide wideband RF input matching.

16. A receiver circuit for mitigating out-of-band blockers, comprising:
means for low noise amplification;
means for down-converting an input signal;
means for filtering the down-converted signal using a current-mode notch filter;
means for amplifying the filtered signal; and
means for re-using a combined supply current of the means for filtering and the means for amplifying to supply the low noise amplification means.

17. The receiver circuit of claim 16, wherein the means for down-converting the input signal is a passive mixer.

18. The receiver circuit of claim 16, wherein the means for filtering the down-converted signal is a current-reuse current-mode notch filter.

19. The receiver circuit of claim 18, wherein the current-reuse current-mode notch filter is powered by redirecting half of the current consumed by the means for amplifying.

20. The receiver circuit of claim 16, wherein the means for low noise amplification is implemented using a capacitive cross-coupled common-gate (CCC-CG) LNTA topology.
